(19) United States
(12) Patent Application Publication
(10) Pub. No.: US 2026/0282248 A1
(43) Pub. Date: Sep. 17, 2026

(54) Speaker and Recorder Device for Word Recall

(71) Applicant: Marisha Bourgeois, Juneau, AK (US)

(72) Inventor: Marisha Bourgeois, Juneau, AK (US)

(21) Appl. No.: 19/264,318

(22) Filed: Jul. 9, 2025

Related U.S. Application Data
(60) Provisional application No. 63/770,839, filed on Mar. 12, 2025.

(51) Int. Cl. G11B 20/10; G11B 33/02; H04R 1/08; H05K 5/00; H05K 5/02

(52) U.S. Cl. CPC H05K 5/0204; H04R 1/08; H05K 5/0018; H04R 2499/11

(57) ABSTRACT

An audio recording device that mounts to a target object to help with word retrieval and recall. The device comprises an electronic system and a system housing, wherein the electronic system is integrated within the system housing. The system housing comprises a playback button on a front panel and a record button on the rear panel. A text label is placed over the playback button displaying the name of the target object. After recording the target word associated with the target object, the user attaches the device to the target object to practice recalling the name of the target object. In an alternative embodiment, the device can also be used to set task reminders. In this embodiment, the user records a daily task and then attaches the device to a convenient location. When the playback button is pressed, the user is reminded of the task to complete.

### FIELD OF THE INVENTION

The present invention relates generally to audio recording and playback devices. More specifically, the present invention is a device that audibly and visibly displays a target word the user wants to recall.

### BACKGROUND OF THE INVENTION

People are sometimes confronted with challenges related to word-finding and recalling. These challenges often occur after a brain injury or a neurological condition. Individuals may also face challenges of word-finding when learning a new language. Some current ways of addressing these challenges is to write the word of the object on the object enabling the person to read and recall the word for the object. Unfortunately, this only aids in presenting the user with a visual representation of the word on the object.

An objective of the present invention is to provide users with a device that records a word spoken by a user, to help with word-finding and recall. The present invention intends to provide users with a device that mounts to the target object. In order to accomplish that, a preferred embodiment of the present invention comprises an electronic system and a system housing. Further, the system housing enables the object to be mounted to the target object. Thus, the present invention is a device that mounts to a target object and records and replays a target word.

### SUMMARY OF THE INVENTION

The present invention is a device that mounts to a target object to help with word retrieval and recall. The present invention seeks to provide users with a device that enables the user to write or play a target word and associate the target word with the target object. To accomplish these objectives, the present invention comprises an electronic system and a system housing. The electronic system comprises all electrical equipment needed to perform the various functions including a microphone, a speaker, a memory drive, a processor, and batteries. To interact with the electronic system, a record button is integrated onto a rear panel of the system housing, while a playback button is integrated onto a front panel of the system housing. The rear panel can be detached, allowing access to the electronic system.

In one configuration, an adhesive label is placed over the playback button which displays the target word associated with the target object. Then, when the playback button is pressed, a recorded audio of the target word is played through the speaker for the user to hear. This allows the user to practice recalling the name of the target object.

In another configuration, the device can also be used to record task reminders. Here, the user can record their voice reminding themselves of what tasks need to be completed. The user can then attach the device to any convenient location and press the playback button to hear the task reminder.

### BRIEF DESCRIPTION OF THE DRAWINGS

FIG. 1 is a top front left perspective view of the present invention.

FIG. 2 is a bottom rear right perspective view of the present invention.

FIG. 3 is a front elevational view of the present invention.

FIG. 4 is a rear elevational view of the present invention.

FIG. 5 is a left-side elevational view of the present invention.

FIG. 6 is a top plan view of the present invention.

FIG. 7 is a top front perspective view of the of the present invention shown attached to a chair, in accordance with a first embodiment.

FIG. 8 is a top front perspective view of the of the present invention shown attached to a storage cabinet, in accordance with a second embodiment.

FIG. 9 is a block diagram of the electrical and electronic components of the present inventions, wherein thicker lines represent electronic connections and thinner lines represent electrical connections.

FIG. 10 is a flowchart of a method of using the present invention, in accordance with the first embodiment of FIG. 7.

FIG. 11 is a flowchart of a method of using the present invention, in accordance with the second embodiment of FIG. 8.

### DETAILED DESCRIPTION OF THE INVENTION

All illustrations of the drawings are for the purpose of describing selected versions of the present invention and are not intended to limit the scope of the present invention.

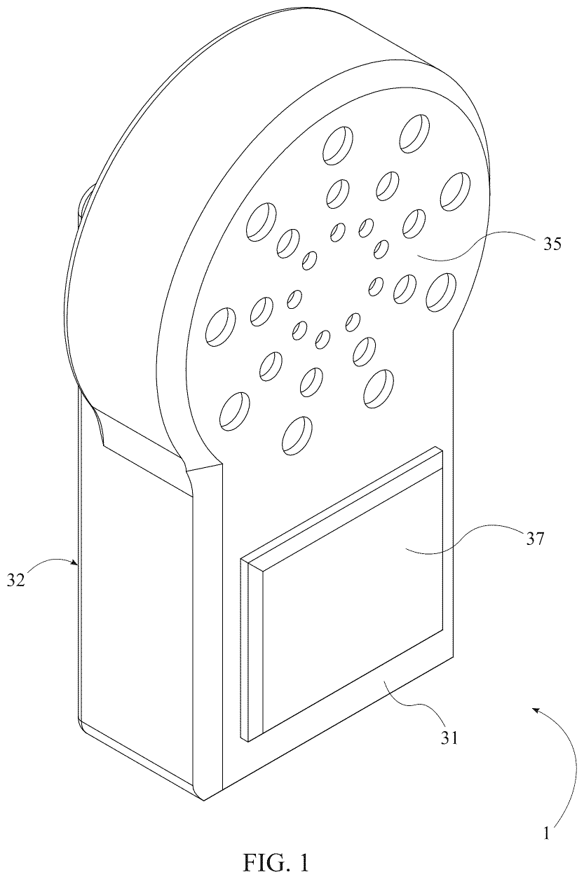

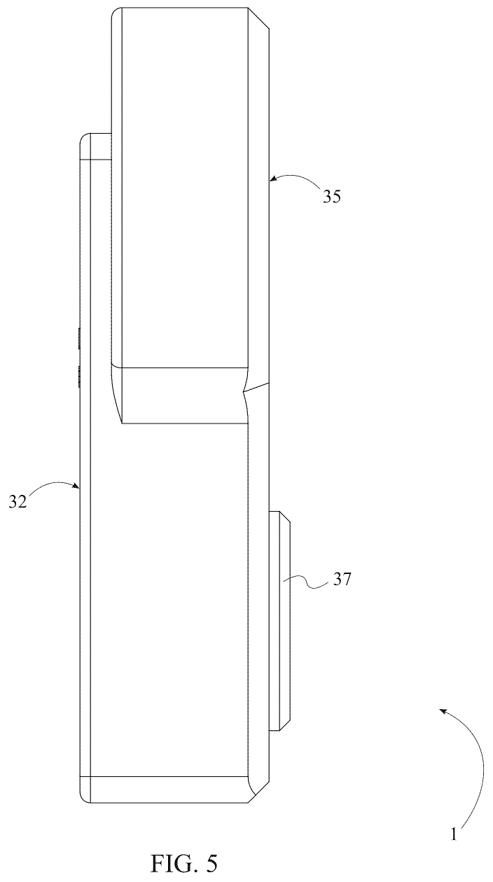

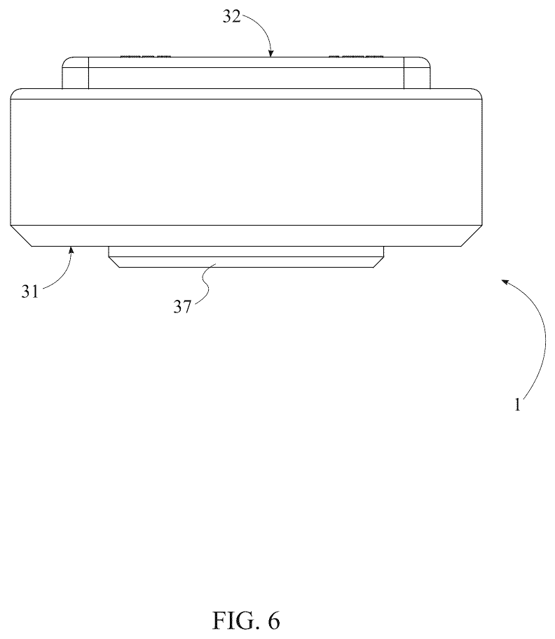

In reference to FIGS. 1-11, the present invention is an audio recording device 1 that is tailored to be used for words and objects that are relevant to the user. An objective of the present invention is to provide users with a device that records and plays a target word when attached to a target object. Hereinafter, the term “target object” refers to a specific item that is the primary focus of attention for the user, and the term “target word” refers to the common name of the target object. For example, if a user is in a room containing multiple objects and the user's attention is focused on one specific object, namely, a chair, then the target object is the chair, and the target word is “chair.” Thus, the present invention intends to provide users with a device that supports users in practicing word-finding and recall of targets objects. Alternatively, as will be explained further, the present invention can also be used to recall daily tasks and task reminders.

To accomplish this objective, the present invention comprises an electronic system 2 and a system housing 3. The electronic system 2 is integrated within the system housing 3 and operatively coupled to a plurality of push buttons located along the exterior of the system housing 3. This arrangement enables the user to interact with the system housing, thus controlling the record and playback functions of the device 1. In all, the present invention is an audio recording device 1 that detachably connects to a target object 10 and is configured for recording the name of the target object (i.e., target word) and playing back the target word 11 for the user to hear.

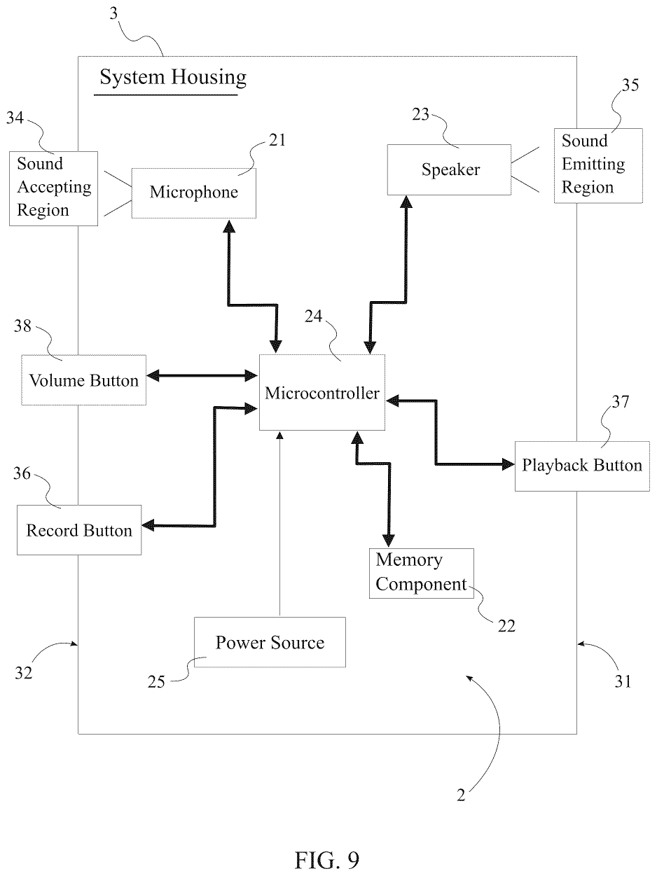

The record and playback functions of the device are performed by the electronic system 2. As seen in FIG. 9, the electronic system 2 comprises a microphone 21, a memory component 22, a speaker 23, a microcontroller 24, and a power source 25. The microphone 21 is configured to capture and record audio input spoken by the user. The memory component 22 is configured to store the recorded audio captured by the microphone 21. And the speaker 23 is configured to play back the recorded audio from the memory component 22 as an audio output. As will be explained further, the microcontroller 24 and the power source 25 help facilitate all of the above functions. This enables a caregiver to record a target word 11 and have the sound of the target word played back as an audio output. The speaker decibel level may be changed, and the audio output may be changed as needed. It is further understood that the electronic system 2 may utilize various types of microphones, speakers, memory components, and power sources without departing from the scope of the present invention.

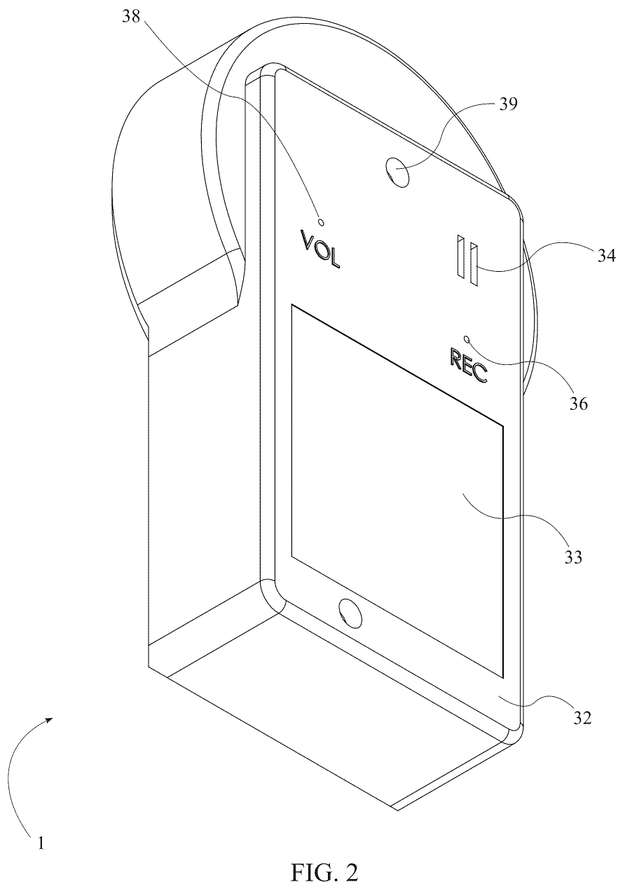

The system housing 3 encompasses the electronic system 2. In the preferred embodiment, the system housing 3 is designed with a rectangular lower section and a rounded upper section. However, it is understood that the shape of the system housing 3 is not limited and can take the form of any suitable shape based on design, user, and/or manufacturing requirements. As best seen in FIGS. 1 and 2, the system housing 3 comprises a front panel 31, a rear panel 32, a mounting surface 33, a sound accepting region 34, a sound emitting region 35, a record button 36, and a playback button 37. The mounting surface 33 is laterally integrated onto the rear panel 32 of the system housing. The mounting surface 33 is designed to enable the device to attach to the target object 10. Preferably, the mounting surface 33 is in the form of an adhesive tape. The adhesive tape is preferably double-sided, allowing the system housing 3 to detachably connect to the target object 10. In another embodiment, the mounting surface 33 can be in the form of a magnet. The magnet can be an external component that is bonded to the rear panel 32 via an adhesive. Alternatively, the magnet can be integrated with the rear panel 32 such that the magnet is formed as part of the rear panel 32. It is understood that other means of attachment may be used without departing from the scope of the present invention.

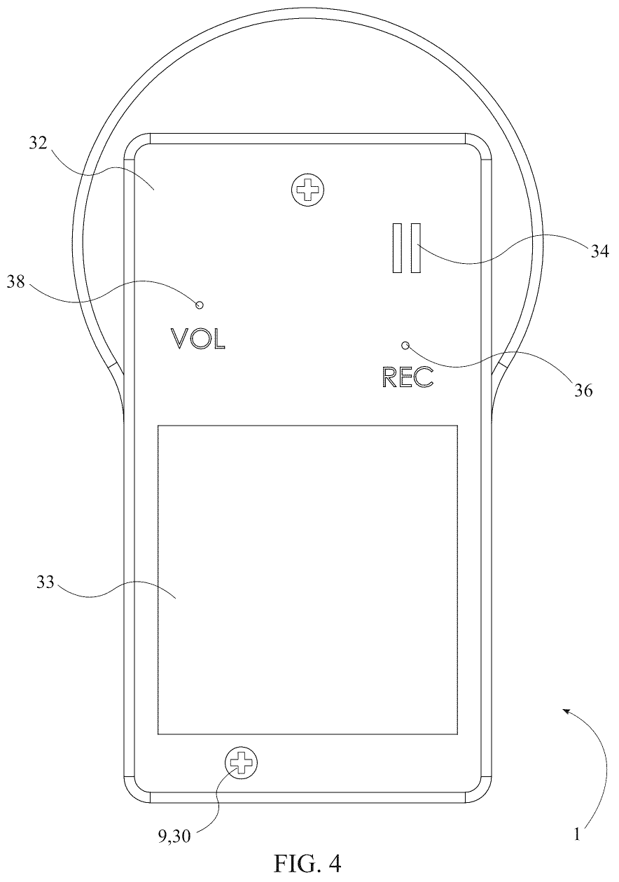

The sound accepting region 34 is positioned along the rear panel 32, preferably adjacent to the microphone 21 or at least in close proximity to the microphone 21. In this arrangement, the sound accepting region 34 provides a clear pathway for the user's voice to travel through the system housing 3 and recorded by the microphone 21. Preferably, as seen in FIG. 4, the sound accepting region 34 is in the form of at least one opening that is laterally integrated into the rear panel 32. Further, the sound accepting region 34 is positioned above the mounting surface 33. In other embodiments, the sound accepting region 34 can be a detachable structure such as a microphone grill. In this embodiment, the microphone grill is detachably connected to a matching-size opening on the rear panel 32.

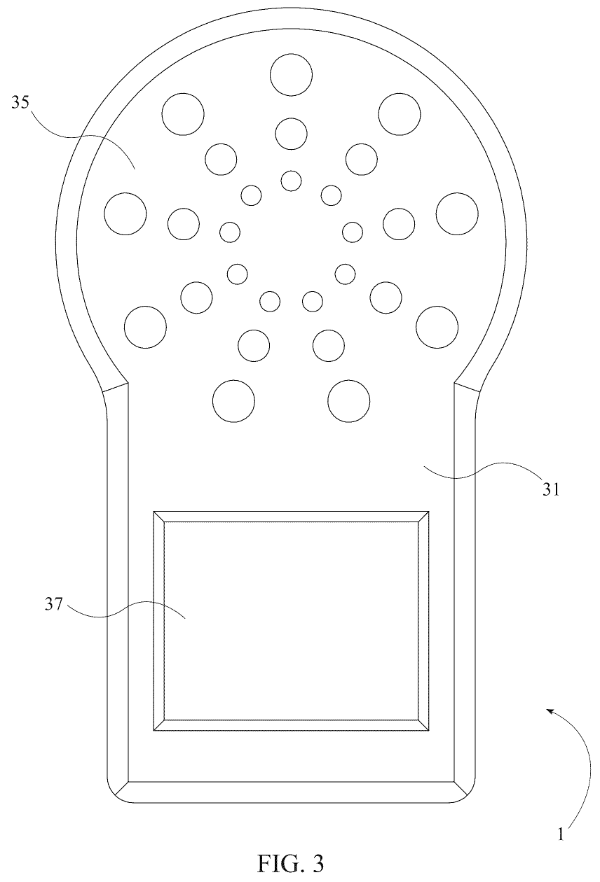

The sound emitting region 35 is positioned along the front panel 31, preferably adjacent to the speaker 23 or at least in close proximity to the speaker 23. In this arrangement, the sound emitting region 35 provides a clear pathway for the recorded audio to be emitted from the speaker 23 and heard by the user from outside the system housing 3. Preferably, as seen in FIG. 3, the sound emitting region 35 is in the form of a plurality of openings that are laterally integrated into the front panel 31. The plurality of openings are positioned above the playback button 37 and arranged in a radial fashion. This arrangement enables the audio output to be easily heard from outside the system housing 3. In other embodiments, the sound emitting region 35 can be a detachable structure such as a speaker grill. In this embodiment, the speaker grill is detachably connected to a matching-size opening on the front panel 31.

The record button 36 is laterally integrated along the rear panel 32 of the system housing. The record button 36 is operably coupled to the microphone 21 through the microcontroller 24. Preferably, as seen in FIG. 2, the record button is recessed into the rear panel, thereby preventing accidental recording when handling the device. When the record button 36 is pressed, the microphone 21 is activated and is configured to capture and store a recorded audio file of the user's voice onto the memory component 22. When the record button 36 is pressed again for a second, third, or N^{th} time, the memory component 22 is configured to overwrite the previous recorded audio file with the latest recorded audio file. This feature allows the user to easily change the recording of the target word 11 as needed. For example, if the user wants to practice recalling the name of another target object, the user can detach the device 1 from the original target object 10, record a new audio file of another target word 11, and attach the device to another target object. When the playback button 37 is pressed, the another target word is played through the speaker 23.

As best seen in FIG. 1, the playback button 37 is a rectangular-shaped button laterally integrated along the front panel 31 of the system housing. In other embodiments, the playback button 37 can take the form of any other suitable shape based on design, user, and/or manufacturing requirements. The playback button 37 is operably coupled to the speaker 23 through the microcontroller 24. When the playback button is pressed, the speaker 23 is activated and is configured to play the recorded audio file stored in the memory component 22.

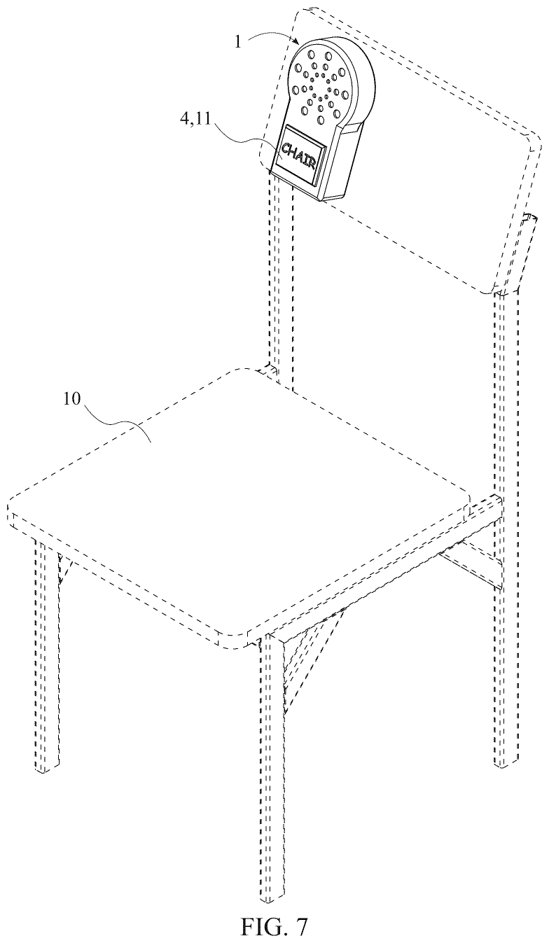

As seen in FIG. 7, when the device is used for word-finding and recall, the playback button 37 may also receive an adhesive label with written text containing the target word. In this embodiment, the device 1 further comprises a text label 4. The text label 4 is affixed to the playback button 37 and is configured to display the target word 11 which identifies the target object 10 by its common name. When the playback button 37 is pressed, the target word 11 recorded as an audio input is played through the speaker 23 as an audio output.

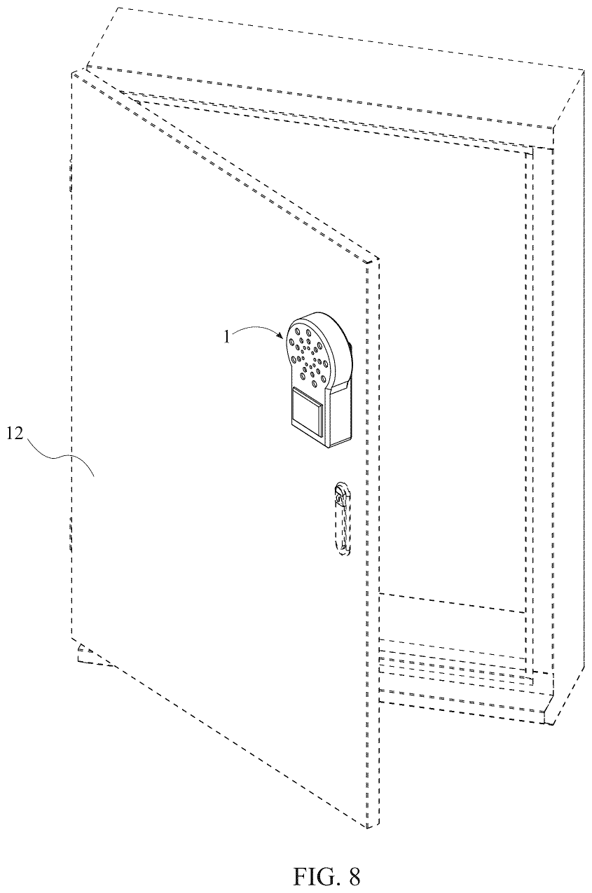

In an alternative embodiment shown in FIG. 8, wherein the device is used for task recall and task reminders, the playback button 37 may be configured without the text label. Rather than attaching the device to a target object 10, the user can attach the device to any arbitrary object 12 selected by the user. In the example shown in FIG. 8, the arbitrary object 12 is a storage cabinet used for storing household cleaning supplies (e.g., window cleaner, gloves, paper towels). When supplies are running low, the user can record a task reminder to pick up additional supplies from the store. Then, before leaving the house, the user can press the playback button 37 to hear the task reminder.

In the preferred embodiment, the system housing 3 further comprises a volume control button 38. The volume control button 38 is laterally integrated along the rear panel 32 of the system housing. The volume control button 38 is operably coupled to the speaker 23 through the microcontroller 24. Preferably, as seen in FIG. 2, the volume control button is recessed into the rear panel 32, thereby preventing accidental misuse when handling the device. When the volume control button 38 is pressed in succession, the microcontroller 24 sends a command signal to the speaker 23 to cycle the volume through each preprogrammed decibel level. This enables the user to adjust the volume of the audio output in increments from low to high.

In the preferred embodiment, the rear panel 32 is a removable cover. In this embodiment, the rear panel 32 comprises a plurality of mounting holes 39. The plurality of mounting holes 39 are aligned with threaded mounting blocks 30 integrated within the system housing 3. A plurality of fasteners 9 traverses through the mounting holes 39 of the rear panel and fastens into the threaded mounting blocks 30, thereby securing the system housing 3 in a closed configuration around the electronic system 2. When the rear panel 32 is removed, the user gains access to the electronic system 2, allowing the user to perform scheduled maintenance on the device (i.e., replace batteries, clean electrical contacts).

In reference to FIG. 9, the microcontroller 24 is a processing device that manages the operation of all electrical components within the system housing 3. The microcontroller 24 receives power from the power source 25. Stated another way, the microcontroller 24 is electrically connected to the power source 25. In the preferred embodiment, the power source 25 is in the form of one or more disposable batteries capable of distributing electrical power to the microcontroller 24 as well as the other electrical components of the present invention. It is understood that the power source 25 is not limited to disposable batteries. Any other type of battery (such as rechargeable batteries), or a combination of various sources of power (such as solar power) may be employed for the smooth functioning of the present invention.

The microcontroller 24 utilizes the recorded audio captured by the microphone 21 for playback through the speaker 23. To perform this function, the microcontroller 24 is electronically connected to each of the microphone 21, the memory component 22, the speaker 23, the record button 36, the playback button 37, and the volume control button 38. The record button 36 is operably coupled to the microphone 21 through the microcontroller 24, wherein operating the record button 36 initiates the microphone 21 to capture and record the user's voice. Stated differently, when the record button 36 is pressed, a command signal is sent to the microcontroller 24 to activate the microphone 21 and begin recording audio.

After recording, the captured audio is converted to an audio data file that is then stored onto the memory component 22. The playback button 37 is operably coupled to the speaker 23 through the microcontroller 24, wherein operating the playback button 37 initiates the speaker 23 to play the recorded audio file stored on the memory component. Stated differently, when the playback button 37 is pressed, a command signal is sent to the microcontroller 24 to retrieve the audio data file from the memory component 22 and transmit the audio data file to the speaker 23 for audio playback.

The memory component 22 is configured for performing data storage and/or data retrieval operations. In general, the memory component 22 may be configured for providing reliable storage of digital information, including but not limited to audio data files. Removable and non-removable storage devices are typical examples of computer storage media that can be used as a type of memory component compatible with the present invention. Computer storage media may include, but is not limited to, microSD cards, flash memory, and internal memory, all of which can be used to store and retrieve audio data files through the microcontroller 24.

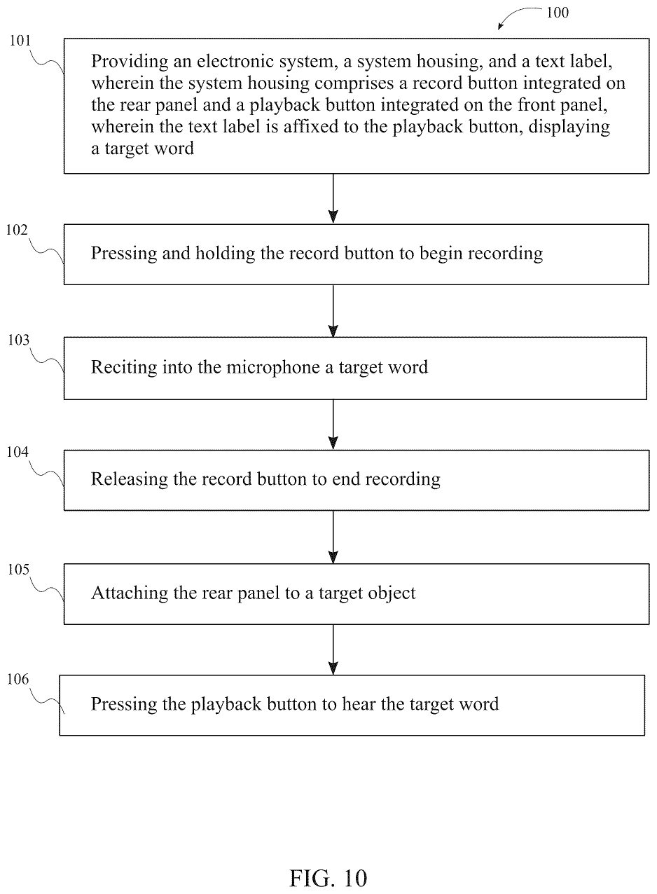

In reference to FIG. 10, a method 100 for using the device for practicing word-finding and recall comprises the following steps. First, at step 101, the method may include providing an electronic system, a system housing, and a text label, wherein the system housing comprises a record button integrated on the rear panel and a playback button integrated on the front panel, wherein the text label is affixed to the playback button, displaying a target word. Next, the user speaks into the microphone, reciting the target word. Specifically, at step 102, the method may include pressing and holding the record button. Subsequently, at step 103, the method may include speaking into the microphone the text written on the text label (i.e., the target word). Subsequently, at step 104, the method may include releasing the record button. After recording, at step 105, the method may include attaching the rear panel of the device onto the target object via the mounting surface. Next, at step 106, the method may include pressing the playback button to hear the recorded audio of the target word.

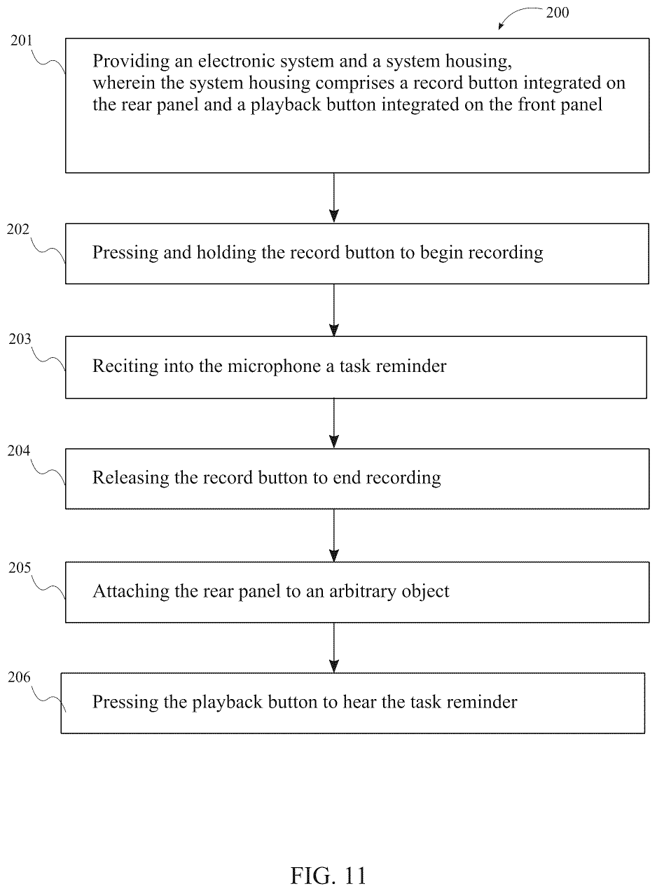

In reference to FIG. 11, a method 200 for using the device for reminding the user of tasks to complete comprises the following steps. First, at step 201, the method may include providing an electronic system and a system housing, wherein the system housing comprises a record button integrated on the rear panel and a playback button integrated on the front panel. Next, the user speaks into the microphone, conveying the target task to complete or target reminder. Specifically, at step 202, the method may include pressing and holding the record button to begin recording. While holding the record button, the step 203 may include speaking/reciting into the microphone the task reminder. Subsequently, at step 204, the method may include releasing the record button to end recording. After recording, at step 205, the method may include attaching the rear panel of the device onto an arbitrary object via the mounting surface. As previously mentioned, the arbitrary object can be any object selected by the user (e.g., storage cabinet). Next, at step 206, the method may include pressing the playback button to hear the task reminder.

Although the invention has been explained in relation to its preferred embodiment, it is to be understood that many other possible modifications and variations can be made without departing from the spirit and scope of the invention.

What is claimed is:

1. An audio recording device comprising:
an electronic system;
a system housing;
the electronic system being integrated within the system housing;
the electronic system comprising a microphone, a speaker, a memory component, a microcontroller, and a power source;
the system housing comprising a front panel, a rear panel, a mounting surface, a record button, and a playback button;
the record button and the mounting surface each being laterally integrated onto the rear panel;
the playback button being laterally integrated onto the front panel; and
the mounting surface of the rear panel being detachably connected to a target object.

2. The audio recording device as claimed in claim 1 comprising:
the microcontroller being electrically connected to the power source;
the record button being operably coupled to the microphone through the microcontroller; and
the playback button being operably coupled to the speaker through the microcontroller.

3. The audio recording device as claimed in claim 2 comprising:
the system housing further comprising a volume control button;
the volume control button being laterally integrated onto the rear panel; and
the volume control button being operably coupled to the speaker through the microcontroller.

4. The audio recording device as claimed in claim 2 comprising:
a text label; and
the text label being affixed to the playback button.

5. The audio recording device as claimed in claim 4 comprising:
the text label displaying a target word; and
the speaker being configured to play the target word when the playback button is pressed.

6. The audio recording device as claimed in claim 2 comprising:
the system housing further comprising a sound accepting region;
the sound accepting region being laterally integrated onto the rear panel, positioned adjacent to the microphone; and
the sound accepting region being in the form of at least one opening.

7. The audio recording device as claimed in claim 6, wherein the rear panel is a removable cover.

8. The audio recording device as claimed in claim 6 comprising:
the system housing further comprising a sound emitting region;
the sound emitting region being laterally integrated onto the front panel, positioned adjacent to the speaker; and
the sound emitting region being in the form of a plurality of openings.

9. The audio recording device as claimed in claim 1, wherein the mounting surface is an adhesive tape.

10. The audio recording device as claimed in claim 1, wherein the mounting surface is a magnet.

11. An audio recording device comprising:
an electronic system;
a system housing;
a text label;
the electronic system being integrated within the system housing;
the electronic system comprising a microphone, a speaker, a memory component, a microcontroller, and a power source;
the system housing comprising a front panel, a rear panel, a mounting surface, a record button, and a playback button;
the record button and the mounting surface each being laterally integrated onto the rear panel;
the playback button being laterally integrated onto the front panel;
the microcontroller being electrically connected to the power source;
the record button being operably coupled to the microphone through the microcontroller;
the playback button being operably coupled to the speaker through the microcontroller;
the text label being affixed to the playback button;
the text label displaying a target word;
the speaker being configured to play the target word when the playback button is pressed;
the mounting surface of the rear panel being an adhesive tape; and
the adhesive tape being detachably connected to a target object.

12. The audio recording device as claimed in claim 11 comprising:
the system housing further comprising a volume control button;
the volume control button being laterally integrated onto the rear panel; and
the volume control button being operably coupled to the speaker through the microcontroller.

13. The audio recording device as claimed in claim 11 comprising:
the system housing further comprising a sound accepting region;
the sound accepting region being laterally integrated onto the rear panel, positioned adjacent to the microphone; and
the sound accepting region being in the form of at least one opening.

14. The audio recording device as claimed in claim 13, wherein the rear panel is a removable cover.

15. The audio recording device as claimed in claim 13 comprising:
the system housing further comprising a sound emitting region;
the sound emitting region being laterally integrated onto the front panel, positioned adjacent to the speaker; and
the sound emitting region being in the form of a plurality of openings.

16. A method for using an audio recording device, the method comprising:
providing an electronic system, a system housing, and a text label;
the electronic system being integrated within the system housing;
the electronic system comprising a microphone, a speaker, a memory component, a microcontroller, and a power source;
the system housing comprising a front panel, a rear panel, a mounting surface, a record button, and a playback button;
the record button and the mounting surface each being laterally integrated onto the rear panel;
the playback button being laterally integrated onto the front panel;
the microcontroller being electrically connected to the power source;
the record button being operably coupled to the microphone through the microcontroller;
the playback button being operably coupled to the speaker through the microcontroller;
the text label being affixed to the playback button;
the text label displaying a target word; and
the mounting surface being an adhesive tape;
pressing and holding the record button to begin recording;
reciting the target word into the microphone;
releasing the record button to end recording;
attaching the rear panel to a target object; and
pressing the playback button to hear the target word.

17. The method as claimed in claim 16 comprising:
detaching the rear panel from the target object;
pressing and holding the record button to begin another recording;
reciting another target word into the microphone;
releasing the record button to end recording;
attaching the rear panel to another target object; and
pressing the playback button to hear the another target word.

18. The method as claimed in claim 16 comprising:
the system housing further comprising a volume control button;
the volume control button being laterally integrated onto the rear panel; and
the volume control button being operably coupled to the speaker through the microcontroller.

19. The method as claimed in claim 16 comprising:
the system housing further comprising a sound accepting region;
the sound accepting region being laterally integrated onto the rear panel, positioned adjacent to the microphone; and
the sound accepting region being in the form of at least one opening.

20. The method as claimed in claim 19 comprising:
the system housing further comprising a sound emitting region;
the sound emitting region being laterally integrated onto the front panel, positioned adjacent to the speaker; and
the sound emitting region being in the form of a plurality of openings.
